(19) United States
(12) Patent Application Publication
(10) Pub. No.: US 2002/0050916 A1
(43) Pub. Date: May 2, 2002

(54) MAGNETORESISTORS

(76) Inventors: JOSEPH PIERRE HEREMANS, TROY, MI (US); DALE LEE PARTIN, RAY, MI (US); THADDEUS SCHROEDER, ROCHESTER HILLS, MI (US)

Correspondence Address: MAGARET A DOBROWITSKY, DELPHI TECHNOLOGIES INC, P O BOX 5052, MAIL CODE 480 414 420, TROY, MI, 480075052

(21) Appl. No.: 09/434,430

(22) Filed: Nov. 4, 1999

(51) Int. Cl. H01L 43/00

(52) U.S. Cl. 338/32 R

(57) ABSTRACT

Doping levels for a magnetoresistor material doped with n-type tellurium (Te) atoms for providing a temperature independent, single element magnetoresistor sensor. In a preferred form, the magnetoresistor material is an epitaxial thin film of indium antimonide (InSb), typically 1.5 micrometers thick, grown on a gallium arsenide (GaAs) substrate having a donor atom concentration between 2×10¹⁷ cm⁻³ and 10×10¹⁷ cm⁻³, wherein a magnetoresistor sensor (50) formed therefrom uses a background magnetic field (418, 420) of between about 0.1 Tesla to about 0.5 Tesla.

### TECHNICAL FIELD

The present invention relates generally to a method of fabricating magnetoresistors.

### BACKGROUND OF THE INVENTION

It is well known in the art that the resistance modulation of semiconductor magnetoresistors can be employed in position and speed sensors with respect to moving magnetic materials or objects (see for example U.S. Pat. Nos. 4,835,467, 4,926,122, and 4,939,456). In such applications, the semiconductor magnetoresistor (MR) is biased with a magnetic field (the background magnetic field) and electrically excited, typically, with a constant current source or a constant voltage source. A magnetic (i.e., ferromagnetic) object rotating relative and in close proximity to the MR, such as a toothed wheel, produces a varying magnetic flux density through the MR, which, in turn, varies the resistance of the MR. The MR will have a higher magnetic flux density and a higher resistance when a tooth of the rotating target wheel is adjacent to the MR than when a slot of the rotating target wheel is adjacent to the MR. The use of a constant current excitation source provides an output voltage from the MR that varies as the resistance of the MR varies.

Increasingly more sophisticated spark timing and emission controls introduced the need for crankshaft sensors capable of providing precise position information during cranking. Various combinations of magnetoresistors and single and dual track toothed or slotted wheels (also known as encoder wheels and target wheels) have been used to obtain this information (see for example U.S. Pat. Nos. 5,570,016, 5,731,702, and 5,754,042).

The electronic control module (ECM) of an engine specifies the required format of the crankshaft position signal. Invariably, the target wheel (i.e., encoder) is designed to generate a magnetic signal conforming to the format of the required signal. That is, preferably, the target wheel will have teeth at crank angles where the position signal should have a high value and slots at crank angles where the position signal should have a low value. The position sensor should convert the mechanical pattern of the target wheel, as closely as possible, into a corresponding electrical signal.

FIG. 1 is a schematic representation of an exemplar automotive environment of use according to this prior art scheme, wherein a target wheel 410 is rotating about an axis 410′, such as for example in unison with a crankshaft, a drive shaft or a cam shaft, and the rotative position thereof is to be sensed. Rotative position of the target wheel 410 is determined by sensing the passage of a tooth edge 412, either a rising tooth edge 412a or a falling tooth edge 412b, using a dual MR differential sequential sensor 50. A tooth edge 412 is considered rising or falling depending upon the direction of rotation of the target wheel 410 with respect to the magnetoresistor sensors MR1 and MR2. MR1 is considered leading and MR2 is considered lagging if the target wheel 410 is rotating in a clockwise (CW) direction whereas if the target wheel is rotating in a counterclockwise (CCW) direction then MR1 is considered lagging whereas MR2 is considered leading. For purposes of example, the target wheel 410 will be assumed to be rotating in a CW direction in the views.

The dual MR differential sequential sensor 50 employs two magnetoresistor elements, MR1 and MR2, which are biased by a permanent magnet 56 (the background magnetic field), wherein the magnetic flux 418 and 420 emanating therefrom are represented by the dashed arrows. The magnetic flux 418 and 420 pass from the permanent magnet 56 through the magnetoresistors MR1 and MR2 and through the air gaps 422 and 424 to the target wheel 410. The target wheel 410 is made of a ferromagnetic material having teeth 426 and spacings 428 therebetween and the sensor signal Vs is available between terminals 430 and 432.

These semiconductor magnetoresistors used in magnetic position sensors, such as crankshaft and camshaft sensors, are currently made commercially by Emcore Corp., in Somerset, N.J., though other manufacturers also make them (Asahi Sensors, Siemens Microelectronics Inc., Midori, Panasonic, etc). Emcore magnetoresistors use an epitaxial thin film of indium antimonide (InSb), typically 1.5 micrometers thick, grown on a gallium arsenide (GaAs) substrate, and doped n-type with tellurium (Te) at an atomic concentration of about 8×10¹⁶ cm⁻³ to 12×10¹⁶ cm⁻³. The average density of electrons in the device is about equal to the average Te atom density. The other manufacturers use InSb films or bulk material with similar Te doping levels. One problem encountered in the use of these devices is that the electrical resistance of each sensor has a large temperature coefficient. These sensors must therefore be used in differential mode as previously described: two magnetoresistors are mounted on an isothermal substrate, and are used to detect spatial variations in the magnetic field, rather than the absolute value of the field.

The resistance of an MR element using an epitaxial thin film of indium antimonide (InSb), typically 1.5 micrometers thick, grown on a gallium arsenide (GaAs) substrate, and doped n-type with tellurium (Te) at an atomic concentration of about 9.4×10¹⁶ cm⁻³ (designated as: InSb:Te at n=9.4×10¹⁶ cm⁻³) similar to the commercial ones, with a length to width ratio of 0.48 (L:W=0.48), is plotted as a function of temperature in FIG. 2, at different values of the background magnetic field (biasing magnetic field), wherein FIG. 2A depicts length L and width W for MR elements 108 demarcated by (gold) shorting bars 110.

It is immediately visible from FIG. 2 that in a position sensing application in which the background magnetic field is modulated between, for example, 0.3 Tesla (T) and 0.4 T, that this results, at approximately −40 degrees Celsius (−40 C.), in a change in resistance from approximately 790 Ohms at point A to approximately 1020 Ohms at point B. A temperature drift from −40 C. to 80 C. in a background field of 0.4 T would result in the same change in resistance from approximately 790 Ohms at point C at a temperature of 80 C. to approximately 1020 Ohms at point B at a temperature of −40 C. It is not possible to distinguish whether the change in resistance is due to a modulation of the background magnetic field between 0.3 T and 0.4 T or to a change in temperature between −40 C. and 80 C. Therefore, the minimum magnetic field modulation that the device, doped n-type with tellurium (Te) at an atomic concentration of about 9.4×10¹⁶ cm⁻³, can resolve with a background magnetic field of 0.4 T in a temperature range of −40 C. to 80 C. is 0.1 T.

This quantity is dependent on (varies with) doping concentration and is designated the “Input Referred Drift” or IRD. The IRD is defined for an MR device as the ratio of the change in resistance of the MR due to temperature drift, for a specified temperature range, divided by the sensitivity wherein the sensitivity is defined as the relative change in resistance of the MR per a specified change in (modulation of) the background magnetic field at a given temperature. The IRD specifies, in effect, the resolution of magnetic field sensors (in Tesla) which is the minimum detectable variation of a magnetic field necessary to compensate for the change in resistance of the device due to temperature drift at a given dopant concentration. That is, the IRD is the minimum detectable variation of a magnetic field, over a specified temperature range and a given background magnetic field, which can be attributed to a magnetic field rather than to a variation in the temperature of the device. The lower the IRD the better the resolution of the MR.

The change in resistance due to temperature drift in the device of FIG. 2, as described above, is too large for it to be useful by itself as an absolute magnetic field sensor, for the background magnetic fields of interest, and the MR devices commercially produced are only usable in differential mode. In differential mode, two MR devices, kept at the same temperature, measure local differences in a magnetic field. However, they are always subject to potential sensing errors due to a potential mismatch between the two MRs. Also, the two MRs being spatially displaced need a larger, more costly bias magnet than that which would be needed for a single MR.

What is needed is a two lead MR device which is temperature independent wherein the sensitivity to a magnetic field is not greatly affected, and which can be used singly.

### SUMMARY OF THE INVENTION

The present invention are new doping levels at which the electrical resistance of the magnetoresistors using an epitaxial thin film of indium antimonide (InSb), typically as follows: 1.5 micrometers thick, grown on a gallium arsenide (GaAs) substrate, and doped n-type with tellurium (Te). These can be made temperature independent, without affecting the sensitivity to a magnetic field too much. Such magnetoresistors can then be used as single elements, i.e., the magnetic field measurement can be obtained from a simple resistance measurement on the new device. The present invention describes the design boundaries for MR device doping levels, InSb film thickness and resistance, and in-plane geometry (i.e. length-to-width ratio) for these magnetoresistors. Specifically, the present invention provides specific doping levels of donor atom concentration between 2×10¹⁷ cm⁻³ and 10×10¹⁷ cm⁻³ as being suitable for magnetoresistors usable as single resistive devices.

Accordingly, it is an object of the present invention to provide a solution to the above mentioned problem.

### BRIEF DESCRIPTION OF THE DRAWINGS

FIG. 1 depicts an example of the prior art environment of use.

FIG. 2 depicts a plot of MR resistance versus temperature for different values of background magnetic fields according to the prior art environment of use.

FIG. 2A depicts the length and width of an MR element.

FIG. 3A depicts one plot of MR resistance versus temperature for different values of background magnetic fields according to the present invention.

FIG. 3B depicts another plot of MR resistance versus temperature for different values of background magnetic fields according to the present invention.

FIG. 4 depicts a plot of IRD (magnetic field resolution) versus Te doping concentration for different values of background magnetic fields according to the present invention.

FIG. 5 shows a plot of electron mobility versus film thickness for two different values of Te doping concentration according to the present invention.

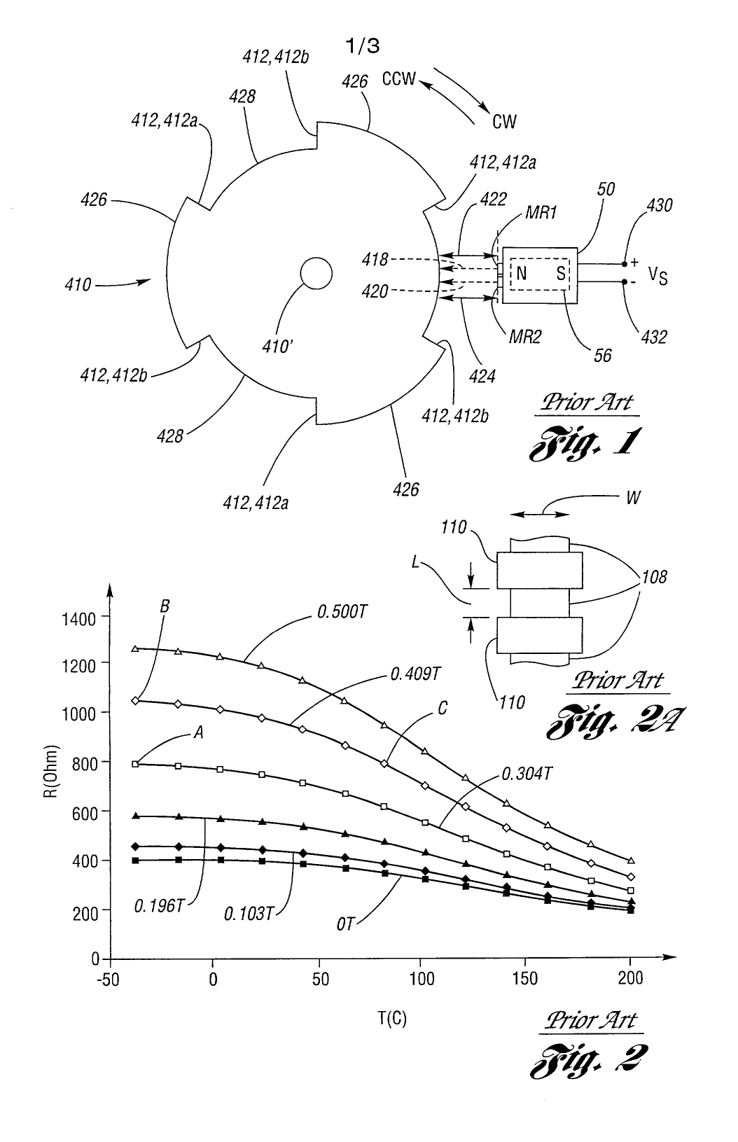

### DESCRIPTION OF THE PREFERRED EMBODIMENT

The present invention is a recipe for fabricating semiconductor MR devices such that they can be used as single resistor elements, and, therefore, are suitable for two-wire operations. The study that leads to the recipe disclosed here was done empirically on InSb films 1.5 micrometers thick, and doped with different densities of Te. Other donors can be used, including tellurium, silicon, sulphur, selenium, tin and the rare earth elements. The independent parameters of the study were thus: the Te doping density, the background magnetic field, and the length-to-width (L:W) ratio (see FIG. 2A) of the devices.

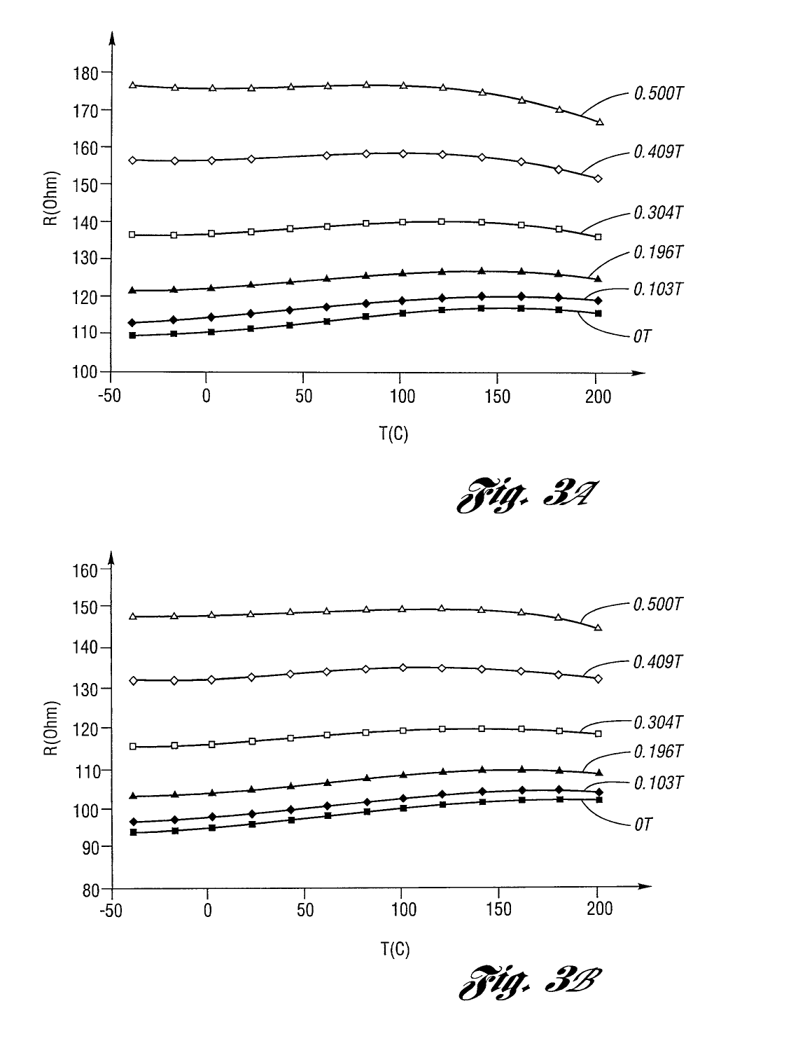

FIG. 3A depicts one empirical plot of resistance versus temperature for different values of background magnetic fields for one near optimal MR device fabricated using an epitaxial thin film of indium antimonide (InSb) 1.5 micrometers thick, grown on a gallium arsenide (GaAs) substrate, and doped n-type with tellurium (Te) at an atomic concentration of about 6.1×10¹⁷ cm⁻³ with a length to width ratio of 0.48 according to the present invention. By comparing FIG. 2 with FIG. 3A, it can be seen that the change in resistance over a temperature range from −40 C. to 80 C. for a given background magnetic field, for example 0.4 T, is much smaller for the device of FIG. 3A. That is, the device of FIG. 3A exhibits a much greater temperature stability at a given background magnetic field than the device of FIG. 2. It can be deduced from the plot of FIG. 3A, as previously done for the device of FIG. 2, that the temperature stability of the device is sufficient to resolve a magnetic field modulation on the order of 0.04 T at a background field of 0.3 T or 0.4 T.

FIG. 3B depicts another empirical plot of resistance versus temperature for different values of background magnetic fields for another near optimal MR device fabricated using an epitaxial thin film of indium antimonide (InSb) 1.5 micrometers thick, grown on a gallium arsenide (GaAs) substrate, and doped n-type with tellurium (Te) at an atomic concentration of about 8×10¹⁷ cm⁻³ with a length to width ratio of 0.48 according to the present invention. By comparing FIG. 2 with FIG. 3B, it can be seen that the change in resistance over a temperature range from −40 C. to 80 C. for a given background magnetic field, for example 0.4 T, is much smaller for the device of FIG. 3B. That is, the device of FIG. 3B exhibits a much greater temperature stability at a given background magnetic field than the device of FIG. 2. It can be deduced from the plot of FIG. 3B, as previously done for the device of FIG. 2, that the temperature stability of the device is also sufficient to resolve a magnetic field modulation on the order of 0.04 T at a background field of 0.3 T or 0.4 T.

By comparing FIG. 3A to FIG. 3B, it can be seen that the device of FIG. 3B, doped with Te to a concentration of 8×10¹⁷ cm⁻³, has a smaller change in resistance at 0.4 T background magnetic field over a temperature range from −40 C. to 200 C. than the device of FIG. 3A over the same temperature range at the same value of the background magnetic field while the device of FIG. 3A, doped with Te to a concentration of 6.1×10¹⁷ cm⁻³, has a smaller change in resistance at 0.3 T background magnetic field over a temperature range from −40 C. to 200 C. than the device of FIG. 3B over the same temperature range at the same value of the background magnetic field. That is, the temperature stability of the device of FIG. 3B is better than the device of FIG. 3A at a background magnetic field of 0.4 T while the temperature stability of the device of FIG. 3A is better than the device of FIG. 3B at a background magnetic field of 0.3 T.

Furthermore, by comparing FIG. 2 with FIG. 3A or FIG. 3B, it can be seen that the device of FIG. 3A, doped with Te to a concentration of 6.1×10¹⁷ cm⁻³, and that the device of FIG. 3B, doped with Te to a concentration of 8×10¹⁷ cm⁻³ have a much smaller change in resistance at all background magnetic fields in the plots over a temperature range from −40 C. to 200 C. than the device of FIG. 2 over the same temperature range for the same values of the background magnetic field. That is, the plots in FIGS. 3A and 3B are much flatter or constant with respect to temperature for all background magnetic fields than the plots in FIG. 2 indicating that the change in resistance of the devices for the temperature range −40 C. to 200 C. is less in FIGS. 3A and 3B than the change in resistance of the device of FIG. 2 for the same temperature range or that the temperature stability of the devices of FIG. 3A and FIG. 3B are much better than the device of FIG. 2 for all background magnetic fields in the plots. These results are expected to hold for doping levels of between about 5×10¹⁷ cm⁻³ and about 9×10¹⁷ cm⁻³.

The actual device length to width geometry (L:W) also influences these results. Devices built with a length-to-width ratio of zero (L:W=0), called Corbino disks, were fabricated and studied as well as devices with L:W ratios as high as 0.64. Empirically, it was found that a device with a low L:W ratio is more sensitive to a magnetic field but has a lower total resistance and a slightly higher temperature sensitivity than devices with high L:W ratios. It was also empirically found that the optimal performance of the MR device is not very sensitive to the L:W parameter. Optimum devices are built with an L:W ratio of between about 0.4 and 0.5, however, L:W ratios of between zero and one may be used, with diminishing sensitivity as L:W nears one.

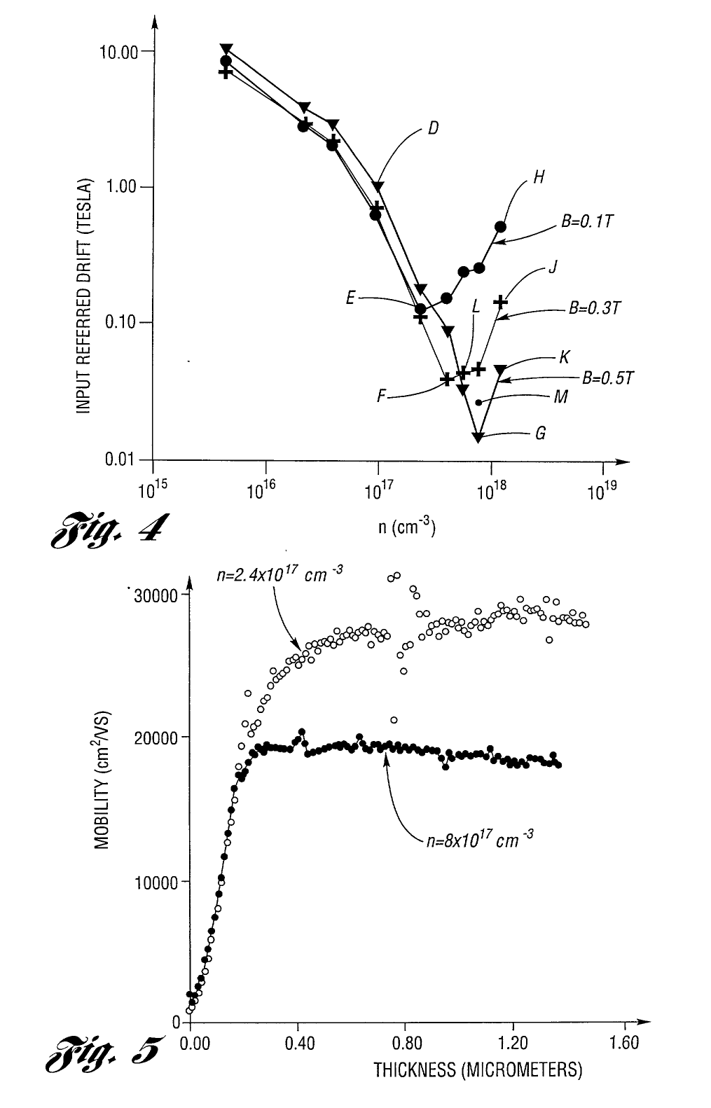

FIG. 4 depicts an empirical plot of IRD (magnetic field resolution) versus doping concentration of fabricated MR devices from films doped with different Te concentration densities, having a length to width ratio of zero (Corbino disks), at different values of the background magnetic field in the temperature range from −40 C. to 200 C. according to the present invention. As previously stated, the IRD is the minimum detectable variation in a magnetic field for a specified temperature range and a given background magnetic field which can be attributed to a magnetic field rather than to a variation in the temperature of the device. The lower the IRD the better the resolution of the MR. Furthermore, from the previous description of the IRD, lower IRDs imply less change in resistance due to temperature variations for a specified temperature range at a given dopant concentration and a given background magnetic field. Thus, points which have the lowest IRDs have the least change in resistance due to temperature variations for a specified temperature range at a particular dopant concentration and a given background magnetic field and represent the optimal detectable variation in a magnetic field for a specified temperature range at a particular doping concentration and a given background magnetic field which can be attributed to a magnetic field rather than to a variation in the temperature of the device.

Hence, each point for a particular background magnetic field in the plot of FIG. 4 represents the minimum detectable variation in a magnetic field in the temperature range from −40 C. to 200 C. for a particular doping concentration and a given background magnetic field which can be attributed to a magnetic field rather than to a variation in the temperature of the device. For example, at point D in FIG. 4 the IRD is approximately 1.00 T at a doping concentration of approximately 1×10¹⁷ cm⁻³ for a background magnetic field of 0.5 T which indicates that the minimum detectable variation in a magnetic field in the temperature range from −40 C. to 200 C. for this doping concentration and background magnetic field which can be attributed to a magnetic field rather than to a variation in the temperature of the device is 1.00 T.

In FIG. 4, the lowest IRD, for a given doping concentration, represents the optimal detectable variation in a magnetic field in the temperature range from −40 C. to 200 C. for a particular doping concentration and a given background magnetic field which can be attributed to a magnetic field rather than to a variation in the temperature of the device. For example, point E represents the optimal detectable variation in a magnetic field, approximately 0.10 T, in the temperature range from −40 C. to 200 C. for a doping concentration of approximately 2×10¹⁷ cm⁻³ and a background magnetic field of 0.1 T which can be attributed to a magnetic field rather than to a variation in the temperature of the device, point F represents the optimal detectable variation in a magnetic field, approximately 0.04 T, in the temperature range from −40 C. to 200 C. for a doping concentration of approximately 4×10¹⁷ cm⁻³ and a background magnetic field of 0.3 T which can be attributed to a magnetic field rather than to a variation in the temperature of the device, and point F represents the optimal detectable variation in a magnetic field, approximately 0.015 T, in the temperature range from −40 C. to 200 C. for a doping concentration of approximately 8×10¹⁷ cm⁻³ and a background magnetic field of 0.5 T which can be attributed to a magnetic field rather than to a variation in the temperature of the device. Thus, it can be ascertained from FIG. 4 that an optimal device built to operate at a background magnetic field of 0.1 T should be doped near a Te concentration of approximately 2×10¹⁷ cm⁻³, an optimal device built to operate at a background magnetic field of 0.3 T should be doped near a Te concentration of approximately 4×10¹⁷ cm⁻³, while an optimal device built to operate at a background magnetic field of 0.5 T should be doped near a Te concentration of approximately 8×10¹⁷ cm^{-3.}

As previously stated, points which have the lowest IRDs have the least change in resistance due to temperature variations for a specified temperature range at a given dopant concentration and a given background magnetic field. Hence, points E, F, and G represent optimal points having the least change in resistance due to temperature variations in the temperature range −40 C. to 200 C. at dopant concentrations of, approximately, 2×10¹⁷ cm⁻³, 4×10¹⁷ cm⁻³ and 8×10¹⁷ cm⁻³, respectively, at background magnetic fields of 0.1 T, 0.3 T, and 0.5 T, respectively. In FIG. 4, point L represents a device in a background magnetic field of 0.3 T having a dopant concentration of, approximately, 6×10¹⁷ cm⁻³ and is very close to the optimal point F. At point L the IRD of the device is, approximately, 0.04 T which is in excellent agreement with the empirical data of FIG. 3A. In FIG. 4, point M is extrapolated from the empirical data of FIG. 4 and represents a device in a background magnetic field of 0.4 T having a dopant concentration of, approximately 8×10¹⁷ cm⁻³ and, by extrapolation from the empirical data, is very close to the optimal point for a background magnetic field of 0.4 T. At point M the IRD of the device is, approximately, 0.03 T which is in excellent agreement with the empirical data of FIG. 3B. Furthermore, since the IRD of point L is very close to the optimal point for a background magnetic field of 0.3 T and point M is very close to the optimal point for a background magnetic field of 0.4 T, it can be inferred from the empirical data of FIG. 4 that the temperature stability of a device with a doping concentration of, approximately, 6×10¹⁷ cm⁻³ should be better than a device with a doping concentration of, approximately, 8×10¹⁷ cm⁻³ in a background magnetic field of 0.3 T whereas the temperature stability of a device with a doping concentration of, approximately, 8×10¹⁷ cm⁻³ should be better than a device with a doping concentration of, approximately, 6×10¹⁷ cm⁻³ in a background magnetic field of 0.4 T. This also agrees with the empirical data of FIGS. 3A and 3B wherein, as previously stated, the temperature stability of the device of FIG. 3B is better than the device of FIG. 3A at a background magnetic field of 0.4 T while the temperature stability of the device of FIG. 3A is better than the device of FIG. 3B at a background magnetic field of 0.3 T.

For a detectable variation of a magnetic field of 0.10 T or less, at doping levels below approximately 2×10¹⁷ cm⁻³ the resistance change of the devices due to temperature variations becomes too large and overwhelms the magnetic field response (i.e. the IRD is greater than 0.10 T) for all background magnetic fields of interest between 0.1 T and 0.5 T, as exemplified by point D in FIG. 4. At doping levels in excess of approximately 10×10¹⁷ cm⁻³ the IRDs of the devices become greater (worse) for all background magnetic fields of interest between 0.1 T and 0.5 T, as exemplified by points H, J and K in FIG. 4 because the sensitivity of the devices to magnetic fields is decreased due to the decrease in electron mobility of the devices with increased doping concentration, as is well known by those skilled in the art. As can be seen in FIG. 4, the IRDs of the devices exceed 0.10 T at points H and J in background magnetic fields of 0.1 T and 0.3 T, respectively, and, by interpolation of the empirical data, the IRD of a device in a background magnetic field of 0.5 T would also exceed 0.10 T at a doping level between 10×10¹⁷ cm⁻³ and 20×10¹⁷ cm⁻³. Therefore, for a detectable variation of a magnetic field of 0.10 T or less operating in background magnetic fields of interest between 0.1 T and 0.5 T, the doping levels of the MR devices should be in the approximate range from 2×10¹⁷ cm⁻³ to 10×10¹⁷ cm⁻³. The present invention discloses a doping range from 2×10¹⁷ cm⁻³ to 20×10¹⁷ cm⁻³ for applications in which a single, passive resistive magnetoresistor is to be used as a magnetic field sensor.

One last question to be addressed is that of the optimal thickness of the film. The mobility and electron density of the films were studied at room temperature, and the results are shown in FIG. 5 for films doped at the two extremes of the claimed doping range.

From FIG. 5, it is concluded that there is little dependence of the mobility on film thickness in epitaxial InSb films doped n-type to the levels indicated, once the thickness exceeds 0.23 micrometers. Since the mobility determines both the sensitivity of the device and the temperature drift (in combination with the electron density), it is clear that the design of the device will work for thicknesses exceeding 0.23 micrometers. For operating temperature ranges extending above 200 degrees C., such as 300 degrees C., the high end of the contemplated doping range (20×10¹⁷ cm⁻³) needs to be used, with the electron mobility now saturating at about 15,000 cm²/V-sec. This would permit the use of a thinner film, such as 0.15 mm, to be used (see FIG. 5).

Whereas all of the present experimental studies were done with indium antimonide (InSb) films on electrically insulating gallium arsenide (GaAs) substrates, other electrically insulating substrate materials could alternatively be used. These include indium phosphide (InP), silicon (Si), mica, and other ceramics or insulators. At very high temperatures, such as 200 degrees C. or higher, silicon is only marginally electrically insulating. In this case, silicon-on-insulator (SOI) or related structures can be used to minimize leakage currents in the substrate. These are covered in U.S. Pat. No. 5,491,461 (issued Feb. 13, 1996), by Partin, Heremans and Green, which patent is hereby incorporated by reference herein. The InSb film can be chemically etched off from the substrate and attached to another substrate with an adhesive, such as an epoxy, if desired. This substrate could include gallium arsenide, SOI, or a ferrite magnet material. We define these structures generically by saying that the InSb is a film.

To those skilled in the art to which this invention appertains, the above described preferred embodiment may be subject to change or modification. Such change or modification can be carried out without departing from the scope of the invention, which is intended to be limited only by the scope of the appended claims.

1. A magnetoresistor die for a single magnetoresistor sensor, comprising:
indium antimonide (InSb) having an n-type doping level comprising a donor atom concentration of between about 2×10¹⁷ cm⁻³ to about 20××10¹⁷ cm⁻³.

2. The magnetoresistor die of claim 1, wherein the InSb is a film.

3. The magnetoresistor die of claim 2, wherein the InSb film is an epitaxial film grown on a gallium arsenide (GaAs) substrate.

4. The magnetoresistor die of claim 3, wherein the InSb epitaxial film has a thickness exceeding about 0.15 micrometers.

5. The magnetoresistor die of claim 1, wherein the donor atom concentration is between about 5×10¹⁷ cm⁻³ and about 7×10¹⁷ cm⁻³; and wherein the InSb magnetoresistor die comprises at least one magnetoresistive element having a length to width ratio of between about 0.4 and about 0.5.

6. The magnetoresistor die of claim 5, wherein the InSb is grown on a gallium arsenide (GaAs) substrate; and wherein the film has a thickness exceeding about 0.23 micrometers.

7. The magnetoresistor die of claim 1, wherein the donor atom concentration is between about 7×10¹⁷ cm⁻³ and about 9×10¹⁷ cm⁻³, and wherein the InSb magnetoresistor die comprises at least one magnetoresistive element having a length to width ratio of between about 0.4 and about 0.5.

8. The magnetoresistor die of claim 7, wherein the InSb is grown on a gallium arsenide (GaAs) substrate; and wherein the film has a thickness exceeding about 0.23 micrometers.

9. The magnetoresistor die of claim 1, wherein the donor atoms are selected from the group consisting of tellurium, silicon, sulfur, selenium, tin and rare earth elements.

10. A magnetoresistor sensor comprising:
a magnetoresistor comprising indium antimonide (InSb) having an n-type doping level comprising a donor atom concentration of between about 2×10¹⁷ cm⁻³ to about 20×10¹⁷ cm⁻³; and
a background magnetic field having a strength of at least about 0.1 Tesla.

11. The magnetoresistor sensor of claim 10, wherein a detectable variation of the magnetic field is between about 0.02 Tesla and about 0.10 Tesla measurable over a temperature range anywhere between about minus forty degrees Centigrade to about plus two hundred degrees Centigrade.

12. The magnetoresistor sensor of claim 10, wherein the magnetoresistor comprises an epitaxial film grown on a gallium arsenide (GaAs) substrate; and wherein the film has a thickness exceeding about 0.23 micrometers.

13. The magnetoresistor sensor of claim 12, wherein a detectable variation of the magnetic field is between about 0.02 Tesla and about 0.10 Tesla measurable over a temperature range anywhere between about minus forty degrees Centigrade to about plus two hundred degrees Centigrade.

14. The magnetoresistor sensor of claim 13, wherein the donor atoms are selected from the group consisting of tellurium, silicon, sulfur, selenium, tin and rare earth elements.
